(19) United States
(12) Patent Application Publication
(10) Pub. No.: US 2024/0130095 A1
(43) Pub. Date: Apr. 18, 2024

(54) RF Attenuation Retro Fit Kit

(71) Applicant: Shielded Opening Solutions, LLC, Sterling, VA (US)

(72) Inventors: James William Starr, Sterling, VA (US); Thomas Randolph Richard Logsdon, Laurel, MD (US)

(21) Appl. No.: 18/379,543

(22) Filed: Oct. 12, 2023

Related U.S. Application Data
(60) Provisional application No. 63/415,502, filed on Oct. 12, 2022.

(51) Int. Cl. H05K 9/00; E06B 5/10; E06B 7/23

(52) U.S. Cl. CPC H05K 9/0015; E06B 5/10; E06B 7/2301; E06B 7/2316; H05K 9/0081

(57) ABSTRACT

A kit for radio frequency shielding a door frame, such as a radio frequency attenuation kit, comprises: an astragal retainer fixed to a door, where the astragal retainer is configured to couple a first radio frequency shielding gasket such that the first gasket overlaps a seam between the door and the door frame; and a second radio frequency shielding gasket which contacts the door when in a closed position, where the second gasket is fixed between a Z bracket and radio frequency tape; wherein the radio frequency tape is applied to the door frame.

### CROSS-REFERENCE TO RELATED APPLICATION

This application claims benefit of U.S. Provisional Application No. 63/415,502 filed Oct. 12, 2022, the disclosure of which is hereby incorporated by reference in its entirety.

### BACKGROUND OF THE INVENTION

### Field of the Invention

This invention relates generally to a radio frequency (RF) and acoustic shielding door kit for openings and, more particularly, a RF and acoustic shielding door kit having improved RF and acoustic attenuation for a shielded openings.

The product is a sound transition class (STC) door and frame assembly installation kit that has been engineered to provide RF Shielding to an already installed door and door frame.

### Description of Related Art

Developments continue to be made in RF shielding and RF shielded rooms for research, medical, military, and other governmental uses. Enclosures with RF shielding, in some cases, also require soundproofing or acoustic insulation in order to protect against the transmission of sound from either within or outside of the shielded enclosure. In production environments, electronics require RF-noise free areas for testing and other activities, and in medical environments, magnetic resonance images provided by MRI operations are distorted by RF that emanates from nearby elevator motors, cell phones, television stations, radio stations, and even passing vehicles. In secure RF shielded environments, there may be a need to improve existing doors to keep electronic and/or audio transmissions from exiting the environment or to prevent electronic and/or audio eavesdropping from outside of the shielded enclosure.

RF and acoustic shielding occurs around the perimeter of the door, namely at the seal and through the door panels. For acoustic purposes, control of the passage of sound waves focuses on the door seal, as well as on the mechanical door for controlling and preventing the passage of sound waves through the air and also by vibration through materials. Current existing doors already installed in doorways may be improved via a kit to increase or add RF shielding and soundproofing. The RF and soundproofing kit must be designed so that they allow the opening to function without changing the operational use and may be installed upon a variety of doors. Moreover, since door alignment post installation is a common problem, any unsealed gaps allow sound wave and RF to travel through.

Government requirements require doors and frames to have both sound attenuation and RF shielding in secure spaces. Most doorways already have a door and frame installed that are lacking or need improvement to RF shielding. This creates an operational issue where the construction of the door requires too much force to seat the door. Thus a need for an improvement to the RF shielding properties of the door exist.

### SUMMARY OF THE INVENTION

In one non-limiting embodiment or aspect of the present disclosure, a kit for radio frequency shielding a door frame, such as a radio frequency attenuation kit, comprises: an astragal retainer fixed to a door, where the astragal retainer is configured to couple a first radio frequency shielding gasket such that the first gasket overlaps a seam between the door and the door frame; and a second radio frequency shielding gasket which contacts the door when in a closed position, where the second gasket is fixed between a Z bracket and radio frequency tape; wherein the radio frequency tape is applied to the door frame.

In one non-limiting embodiment or aspect of the present disclosure, the kit may include an L bracket configured to cover the Z bracket and fix to the door frame and Z bracket.

In one non-limiting embodiment or aspect of the present disclosure, the kit may include an offset bracket fixed to the door and configured to couple a third radio frequency shielding gasket with peel and stick tape between the door surface and the offset bracket.

In one non-limiting embodiment or aspect of the present disclosure, the kit may include the third gasket extending downward and contacting a threshold when the door is in a closed position.

In one non-limiting embodiment or aspect of the present disclosure, the kit may include at least one radio frequency shielding gasket between the threshold and a floor.

In one non-limiting embodiment or aspect of the present disclosure, the kit may include that the third gasket is a multi-layered gasket.

In one non-limiting embodiment or aspect of the present disclosure, the kit may include the first and second radio frequency gaskets including a foam core.

In one non-limiting embodiment or aspect of the present disclosure, the kit may include the second radio frequency insulating gasket contacting the radio frequency tape.

In one non-limiting embodiment or aspect of the present disclosure, the kit may include peel and stick tape applied between the surface of the door and/or door frame and the gaskets.

In one non-limiting embodiment or aspect of the present disclosure, the kit may include a door frame, such as a radio frequency attenuation kit, comprising: an astragal retainer fixed to a first side of a door and configured to extend beyond the edge of the door to couple a first radio frequency gasket; a second radio frequency gasket fixed to a door frame which contacts a second side of the door when the door is in a closed position; and a first bracket fixed to the door frame and configured to fix the second radio frequency gasket to the door frame.

In one non-limiting embodiment or aspect of the present disclosure, the kit may include a second astragal retainer fixed to the door.

In one non-limiting embodiment or aspect of the present disclosure, the kit may include a third gasket configured to fit between the door and the second astragal retainer which extends downward and contacts a threshold when the door is in a closed position.

In one non-limiting embodiment or aspect of the present disclosure, the kit may include at least one radio frequency shielding gasket between the threshold and a floor.

In one non-limiting embodiment or aspect of the present disclosure, the kit may include the radio frequency gaskets including a foam core and wrapped in a radio frequency tape.

In one non-limiting embodiment or aspect of the present disclosure, the kit may include the third gasket as a multi-layered gasket.

In one non-limiting embodiment or aspect of the present disclosure, the kit may include RF peel and stick tape applied between the surface of the door and/or door frame and the gaskets.

In one non-limiting embodiment or aspect of the present disclosure, the kit may include the surface of the door and door frame configured to expose a groundable surface material.

In one non-limiting embodiment or aspect of the present disclosure, the kit may include the astragal retainers fixed to the door and the brackets fixed to the door frame with machine screws.

In one non-limiting embodiment or aspect of the present disclosure, the kit may include an astragal retainer fixed to a door, where the astragal retainer is configured to couple a first radio frequency shielding gasket such that the first gasket overlaps a seam between the door and the door frame; a second radio frequency insulating gasket which contacts the door when in a closed position, the second gasket is fixed between a Z bracket and the door frame; an L bracket configured to cover the Z bracket and fix directly to the door frame and Z bracket; and a second astragal retainer fixed to the door and configured to couple a third radio frequency shielding gasket between the door surface and the second astragal retainer; wherein radio frequency tape is applied to the door surface and door frame surface where the astragal retainers and the gaskets contact the surfaces to electrically bond the door to the door frame.

In one non-limiting embodiment or aspect of the present disclosure, the kit may include the third gasket extending downward and contacting a threshold when the door is in a closed position.

### BRIEF DESCRIPTION OF THE DRAWINGS

Other features, advantages, and details of the present invention will emerge on reading the following description of several embodiments of the invention given by way of illustration and not being limiting, said description being made with reference to the appended drawings.

FIG. 1 displays a view of an example of a door;

FIG. 2 displays a section view of an example of an edge of the door;

FIG. 3 displays a section view of an example of a sill section;

FIG. 4 displays a section view of another example of a sill section;

FIG. 5 displays a section view of another example of a sill section; and

FIG. 6 displays a section view of a second example of an edge of the door.

### DESCRIPTION OF THE INVENTION

Characteristics of the present invention, as well as the methods of operation and functions of the related elements of structures and the combination of parts and economies of manufacture, will become more apparent upon consideration of the following description with reference to the accompanying drawings, all of which form a part of this Specification. It is to be expressly understood, however, that the drawings are for the purpose of illustration and description only, and are not intended as a definition of the limits of the invention. As used in the specification and the claims, the singular form of “a”, “an”, and “the” include plural referents unless the context clearly dictates otherwise. It is to be understood that the specific devices and processes illustrated in the attached drawings, and described in the following Specification, are simply exemplary embodiments of the invention. Hence, specific dimensions and other physical characteristics related to the embodiments disclosed herein are not to be considered as limiting.

Referring to the figures, wherein like numerals of reference designate like elements throughout the several views, a radio frequency (RF) shielding and acoustic attenuation door 10 having improved RF and acoustic attenuation for a room entry way is illustrated. The shielding door may also have an improved shield against electromagnetic emissions which cause disturbances in other pieces of electrical equipment. The shielding door 10 is designed for commercial and security applications, and it provides the opening and closing forces associated with a conventional shielding room entryway door. In addition, the shielding door 10 may include single or double cylinder deadbolts, door closers, magnetic switches, medium or high security combination locks, or other specified door hardware to suit the particular application. Conductive tape may be applied throughout the sections of the door 10, door frame 1000, and kit. Conductive tape is used to increase the grounding capabilities of the door 10 and door frame 1000.

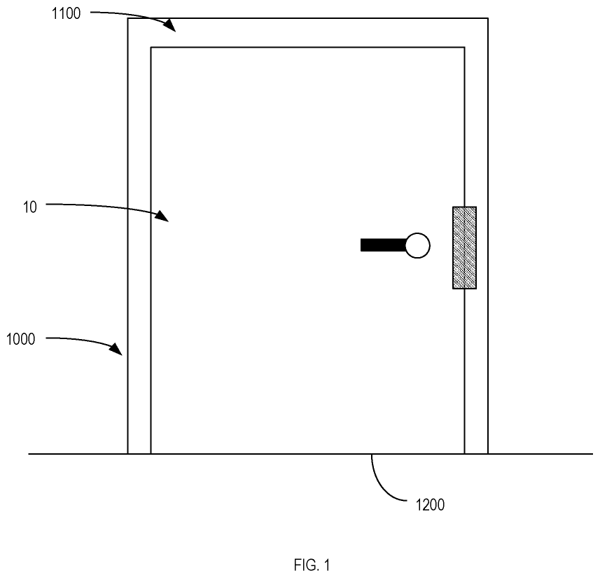

FIGS. 1-4 display a shielding door 10 within a door frame including at least one door hinge 100 that is hingedly attached to a door frame 1000, which may be a portion of the wall of the room to which the shielding door 10 is mounted or rotationally fixed to by the door hinge 100. The door 10 being hingedly connected to a wall may have a push side and a pull side, which may either be referred to as the first side or second side. The door 10 is preferably made of a conductive metal, but may be any composition. The door 10 is mounted to the door frame 1000 using the hinge 100 that is designed and may be installed to ground the door 10. The shielding door 10 is illustrated as a single door, but is not so limited; the shielding door 10 can be constructed as a double door. The shielding door may also include an electric power transfer to allow an electrical contact to connect power from the frame 1000 into the door 10 and to the lock. The shielding door 10 may also include a handle and lock directly attached to the electric power transfer to allow control of the lock. The door frame 1000 may be made of a head section, jamb sections 1100 and the sill section 1200.

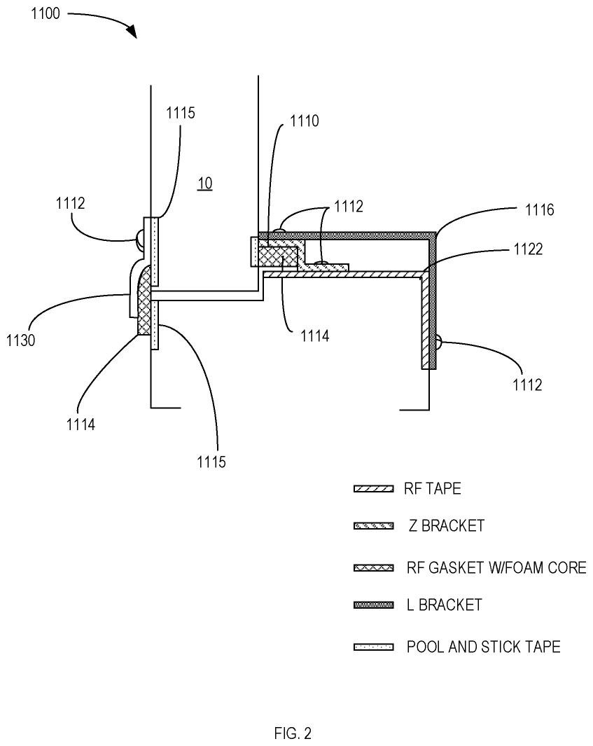

FIG. 2 displays a cross section of the jamb section 1100 of the door and door frame 1000 with the kit installed. The jamb section 1100 includes a Z-bracket 1110 which is attached to the RF gasketing via an attachment means. The Z-bracket 1110 may be configured to hold the RF gasket 1114 and be Z-shaped to contact the door frame 1000. The attachment means may include a bolt, screw, nail, rivet, adhesive, or similar means. This attachment means anchors the jamb section 1100 to the wall. Coupled to the bracket 1110 by a retainer cover screw 1112 is an RF gasket 1114. An L-shaped bracket 1116 covering the attachment means is connected to the Z-shaped bracket 1110 by the retainer cover screws 1112. The RF gasket 1114 separates a section of the Z-shaped bracket 1110 and door frame 1000. The RF gasket 1114 may shield door 10 when the door 10 is in a closed position by contacting the door 10. The RF gasket 1114 may act to seal the door 10 when the door 10 is in the closed position. The RF gasket 1114 may consist of a foam material that is wrapped in an RF fabric to give it gasket properties as well as RF shielding properties. The RF gasket 1114 may be made of multiple layers of neoprene or multiples layers of the wrapped gaskets, which increase the RF seal between the jamb section 1100 and the door 10. The RF gasket 1114 may contact a RF peel and stick tape 1115. The retainer cover screw 1112 may connect through any one of or all of the Z-shaped bracket 1110, the RF gasket 1114, and L-shaped bracket 1116. Advantageously, the RF gasket 1114 included are oversized to account for variations in the construction to mitigate RF leak. Advantageously, the frame 1000 and jamb sections 1100 which are included in the system are fully adjustable to allow for variation in the construction of the wall to obtain RF shielding because of the Z-shaped bracket 1110 and L-shaped bracket 1116 configuration. Advantageously, the kit may be applied to any door to increase the RF shielding properties of the door and door frame. Additionally, the gaskets of the system are sized and shaped to allow for variances in the adjustments of the sections.

FIG. 2 further displays an astragal retainer 1130 attached to the door 10 and configured to couple an RF gasket 1114 to the door 10. The astragal retainer 1130 may be fixed to the door with any attachment means, and may include a bolt, screw, nail, rivet, or similar means. The RF gasket 1114 and astragal retainer 1130 may overlap the seam between the door 10 and door frame 1000. This advantageously increases the RF shielding abilities of the door 10 and door frame 1000. RF Peel and stick tape 1115 may be applied to the door 10 and door frame 1000 at the points of contact between the astragal retainer 1130 and RF gasket 1114. Peel and stick tape or conductive tape 1122 may include a RF mask and peel style tape and RF foil which increases the RF shielding properties of the surface it is applied to.

As shown in the figures, the hinge 100 may rotatably fix the jamb section 1100 to the door 10. The hinge 150 may be a cam-lift style hinge or a similar hinge type. The hinge 100 may be bolted or screwed to the jamb section 1100 and door 10 such that when the door 10 is in the closed position, the first arm 102 and second arm 104 of the hinge 100 are aligned along a plane.

Advantageously, conductive RF tape 1122 may be applied to the Z-shaped bracket 1110, L-shaped bracket 1116, and each conductive surface to seal gaps and ground the door 10 and frame 1000 to attenuate RF transmission. Conductive tape 1122 may be applied to all sides of the frame 1000 which the Z-shaped bracket 1110 and L-shaped bracket 1116 are fixed over. Conductive tape 1122 may include a RF mask and peel style tape and RF foil. The conductive tape 1122 may be applied to a conductive metal or composite surface. This electrically bonds the materials the tape 1122 is applied to for grounding.

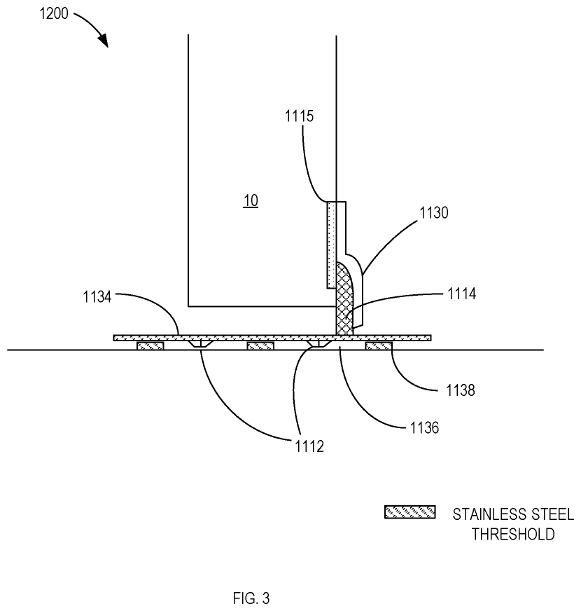

Further, FIG. 3 displays a cross section of the bottom of the door 10. Fixed to the bottom of the door is an astragal retainer 1130. The retainer 1130 may be fixed by any fixing means, included but not limited to bolts, screws, nails, rivets, or similar means. The retainer 1130 is configured to hold an RF gasket 1114 to the door 10. The RF gasket 1114 may be a single layered gasket or multiple gaskets stacked. The retainer 1130 may be configured so the RF gasket 1114 extends downward towards the threshold 1134 of the door 10 and may contact the threshold 1134 when the door 10 is in a closed position and further aid in dampening sound and increasing RF shielding properties. The threshold 1134 is fastened to the floor surface with screws 1112 and may include a cavity or spacing 1136 for threshold gaskets 1138 to be located between the floor and threshold. The retainer 1130 and RF gasket 1114 may be separated from the door by RF peel and stick tape or conductive tape 1122. Conductive tape 1122 may be applied to the bottom of the door 10 to further electrically ground the door 10 when in the closed position. The conductive tape 1122 may be applied to the retainer bracket 1130 as well as other sections of the door 10. Conductive tape 1122 may advantageously be applied between the door 10 and the gasket 1114 and further at the bottom of the door 10. The conductive tape 1122 may even be applied to the floor if it is bare metal to facilitate conduction through the threshold 1134 to the floor.

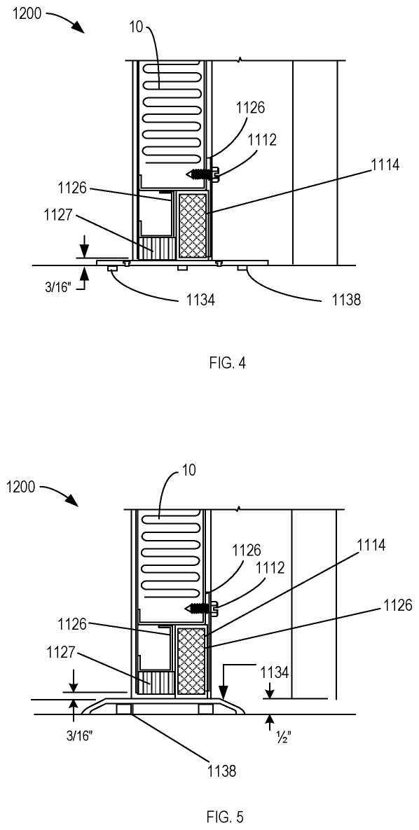

FIGS. 4 and 5 display another embodiment of a cross section of the bottom of the door 10. The sill section 1200 includes a threshold 1134 which is fixed to the ground or floor surface. The threshold 1134 may be configured such that the bottom of the door 10 contacts the top surface of the threshold 1134. The threshold, as shown in FIG. 5, may be configured such that a cavity or chamber below the bottom surface of the threshold 1134 and floor surface exists. The threshold 1134 may be substantially flat otherwise. The threshold 1134 may be made of any material that allows for conductive grounding. The sill section 1200 may further include threshold gaskets 1138. The threshold 1134 covers the gasket 1138. The gaskets 1138 further help to shield RF and/or electrically bond the sill section 1200 and may be made of a RF conductive material. The threshold 1134 may be fixed to the ground or floor surface which is compressed against the floor to aid in sealing against RF leaks which may have gone under the door 10.

Further, FIG. 4 displays a cross section of the bottom of the door 10. The bottom of door 10 may include the RF gasket 1114 which may extend from the bottom of the door 10. The gasket 1114 may contact the threshold and further aid in dampening sound. The gasket 1114 may be a multilayered gasket. The gasket 1114 may be a neoprene or neoprene like material wrapped in a conductive radio frequency material. RF or conductive tape 1122 may be applied to the bottom of the door 10 to further electrically ground the door 10 to the gaskets 1114 when in the closed position. The conductive tape 1122 may be applied to other sections of the door 10 and gasket. Conductive tape 1122 may advantageously be applied at the bottom of the door 10 where the gasket is fastened to the door 10. Advantageously, this section of the bottom of the door 10 including the gasket 1114 and RF shielding properties may be an attachment that is fastened to the bottom of the door 10 during installation of the kit.

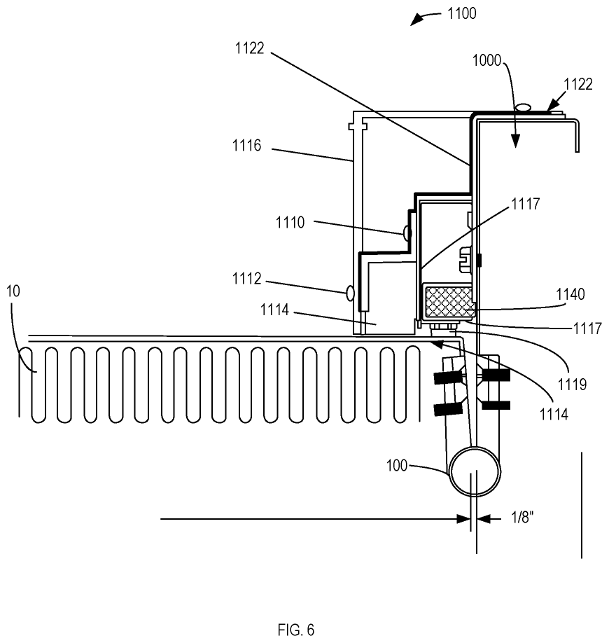

FIG. 6 displays a cross section of the jamb section 1100 of the door and door frame 1000 with another embodiment of the kit installed. The jamb section includes a Z-shaped bracket 1110 which is fixed to the sound gasketing retainer cover 1117 via an attachment means. The attachment means may include a bolt, screw, nail, rivet, or similar means. This attachment means anchors the jamb section 1100 to the wall. An L-shaped bracket 1116 covering the attachment means is connected to the Z-shaped bracket 1110 by the retainer cover screw 1112. In-between the anchoring point of the attachment means and the hinge 100 are an RF gasket 1114 and sound insulation 1140. The RF gasket 1114 may shield the sound door 10 when the door 10 is in a closed position by contacting the door 10. The RF gasket 1114 seals the door 10 when the door 10 is in the closed position. The RF gasket 1114 may be made of multiple layers, which increase the RF seal between the jamb section 1100 and the door 10. The sound insulation device 1140 may be nested under the Z-shaped bracket 1110 and the RF gasket 1114. The sound insulation gasketing 1140 may further insulate the jamb section 1100 and aid in increasing the acoustic attenuation. The sound insulation device 1140 may be a neoprene sponge or any other similar material for dampening and may be wrapped in RF tape. The retainer cover screw 1112 may connect through any one of or all of the L-bracket 1116, RF gasket 1114, and sound insulation gasketing 1140. Advantageously, the RF gaskets 1114 included are oversized to account for variations in the construction. Advantageously, the frame 1000 and jamb sections 1100 which are included in the system are fully adjustable to allow for variation in the construction of the wall to obtain RF shielding because of the Z-bracket 1110 and L-bracket 1116 configuration. Additionally, the gaskets of the system are sized and shaped to allow for variances in the adjustments of the sections.

The hinge 100 may rotatably fix the jamb section 1100 to the door 10. The hinge 100 may be a cam-lift style hinge or level swing hinge or a similar hinge type. The hinge 100 may be bolted or screwed to the jamb section 1100 and door 10 such that when the door 10 is in the closed position, the first arm and second arm of the hinge 100 are aligned along a plane. When the hinge 100 is in a fully closed position, the door 10 is sealed against the frame 1000 and the door 10 contacts a seal 1119 which further seals the door 10.

Advantageously, conductive tape 1122 may be applied to the frame of the door 10 and over the pre-existing sound seal. Brackets 1110 and 1116 may be installed over the conductive tape 1122 to bond the frame of the door 10. Conductive tape 1122 may be applied to the Z-shaped bracket 1110, L-shaped bracket 1116, and each conductive surface to ground the door 10 and frame 1000 to attenuate RF transmission. Conductive tape 1122 may be applied to all sides of the frame 1000 and over top of the sound gasketing retainer cover 1117. Conductive tape 1122 may include a RF mask and peel style tape and RF foil. The conductive tape 1122 may be applied by preparing a surface for application, adding a conductive foil, being aluminum, copper, or a conductive material, to the frame, and then applying the conductive tape 1122. This electrically bonds the materials to the tape 1122 that is applied to for grounding.

Whereas, the invention has been described in relation to the drawings and claims, it should be understood that other and further modifications, apart from those shown or suggested herein, may be made within the scope of this invention.

The invention claimed is:

1. A kit for radio frequency shielding a door frame, such as a radio frequency attenuation kit, comprising:
an astragal retainer fixed to a door, the astragal retainer is configured to couple a first radio frequency shielding gasket such that the first gasket overlaps a seam between the door and the door frame and the door and door frame are electrically bonded; and
a second radio frequency shielding gasket which contacts the door when in a closed position, the second gasket is fixed between a Z bracket and radio frequency tape,
wherein the radio frequency tape is applied to the door frame.

2. The kit of claim 1, further comprising: an L bracket configured to cover the Z bracket and fix to the door frame and Z bracket.

3. The kit of claim 1, further comprising an offset bracket fixed to the door and configured to couple a third radio frequency shielding gasket with RF peel and stick tape between the door surface and the offset bracket.

4. The kit of claim 3, further comprising the third gasket extends downward and contacts a threshold when the door is in a closed position.

5. The kit of claim 4, further comprising at least one radio frequency shielding gasket between the threshold and a floor.

6. The kit of claim 3, wherein the third gasket is a multi-layered gasket.

7. The kit of claim 1, wherein the first and second radio frequency gaskets include a foam core.

8. The kit of claim 1, further comprising the second radio frequency shielding gasket, contacts the radio frequency tape.

9. The kit of claim 3, further comprising RF peel and stick tape applied between the surface of the door and/or door frame and the gaskets.

10. A kit for radio frequency shielding a door frame, such as a radio frequency attenuation kit, comprising:
an astragal retainer fixed to a first side of a door and configured to extend beyond the edge of the door to couple a first radio frequency gasket;
a second radio frequency gasket fixed to a door frame which contacts a second side of the door when the door is in a closed position; and
a first bracket fixed to the door frame and configured to fix the second radio frequency gasket to the door frame.

11. The kit of claim 10, further comprising a second astragal retainer fixed to the door.

12. The kit of claim 11, further comprising a third gasket configured to fit between the door and the second astragal retainer which extends downward and contacts a threshold when the door is in a closed position.

13. The kit of claim 12, further comprising at least one radio frequency shielding gasket between the threshold and a floor.

14. The kit of claim 12, wherein the radio frequency shielding gaskets includes a foam core and are wrapped in a radio frequency material.

15. The kit of claim 10, wherein the third radio frequency shielding gasket is a multi-layered gasket.

16. The kit of claim 13, further comprising RF peel and stick tape applied between the surface of the door and/or door frame and the radio frequency shielding gaskets.

17. The kit of claim 13, wherein the surface of the door and door frame are configured to expose a groundable surface material.

18. The kit of claim 11, wherein the astragal retainers is fixed to the door and the brackets are fixed to the door frame with machine screws.

19. A kit for radio frequency shielding a door frame, such as a radio frequency attenuation kit, comprising:
an astragal retainer fixed to a door, the astragal retainer is configured to couple a first radio frequency shielding gasket such that the first gasket overlaps a seam between the door and the door frame;
a second radio frequency shielding gasket which contacts the door when in a closed position, the second gasket is fixed between a Z bracket and the door frame;
an L bracket configured to cover the Z bracket and fix directly to the door frame and Z bracket; and
a second astragal retainer fixed to the door and configured to couple a third radio frequency shielding gasket between the door surface and the second astragal retainer,
wherein radio frequency tape is applied to the door surface and door frame surface where the astragal retainers and the gaskets contact the surfaces.

20. The kit of claim 19, wherein the third radio frequency shielding gasket extends downward and contacts a threshold when the door is in a closed position.
